(19) United States
(12) Patent Application Publication
(10) Pub. No.: US 2026/0237428 A1
(43) Pub. Date: Aug. 13, 2026

(54) MEMORY CIRCUITS WITH REDUCED NUMBER OF WL BOOSTERS AND METHODS FOR OPERATING THE SAME

(71) Applicant: Taiwan Semiconductor Manufacturing Company, Ltd., Hsinchu (TW)

(72) Inventor: Masayuki Ichikawa, Hsinchu City (TW)

(73) Assignee: Taiwan Semiconductor Manufacturing Company, Ltd., Hsinchu (TW)

(21) Appl. No.: 19/050,478

(22) Filed: Feb. 11, 2025

(51) Int. Cl. G11C 11/418; G11C 11/412

(52) U.S. Cl. CPC G11C 11/418; G11C 11/412

(57) ABSTRACT

A memory circuit includes a memory array comprising a plurality of memory cells arranged across a first number (N) of word lines; a word line driver comprising a second number (N/2) of logic gates, wherein each of the logic gates is configured to receive a first input signal corresponding to a first one of the word lines and a second input signal corresponding to a second one of the word lines, and configured to provide a boost signal based on respective logic states of the first and second input signals; and a booster circuit comprising N/2 pairs of first and second buffers, wherein each of the first buffers is configured to receive the corresponding boost signal and de-assert the corresponding first word line, and each of the second buffers is configured to receive the corresponding boost signal and assert the corresponding second word line.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a memory circuit including a WL driver circuit and a WL booster circuit physically disposed on opposite ends of memory array, respectively, in accordance with some embodiments.

FIG. 2 illustrates a circuit diagram of a memory cell of the memory array of the memory circuit of FIG. 1, in accordance with some embodiments.

FIG. 3 illustrates an example circuit implementation of the memory circuit of FIG. 1, in accordance with some embodiments.

FIG. 4 illustrates waveforms of various signals while operating the memory circuit of FIG. 3, in accordance with some embodiments.

FIG. 5 illustrates an example circuit implementation of one buffer of the WL booster circuit of the memory circuit of FIG. 1, in accordance with some embodiments.

FIG. 6 illustrates a schematic diagram of another memory circuit including a WL driver circuit and a WL booster circuit physically disposed on opposite ends of memory array, respectively, in accordance with some embodiments.

FIG. 7 illustrates waveforms of various signals while operating the memory circuit of FIG. 6, in accordance with some embodiments.

FIG. 8 illustrates a schematic view of a portion of the memory circuit of FIG. 1 or 6, in accordance with some embodiments.

FIG. 9 illustrates a schematic diagram of yet another memory circuit including a WL booster circuit physically interposed between a first memory array and a second memory, in accordance with some embodiments.

FIG. 10 illustrates an example circuit implementation of the memory circuit of FIG. 9, in accordance with some embodiments.

FIG. 11 illustrates an example flow chart of a method for operating a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Generally, in order to write a data bit to a memory cell, a word line (WL) is asserted to activate the respective access (or pass-gate) transistors of the memory cell. While the WL is asserted, appropriate biases are applied to bit lines (BLs) to write the data bit to the memory cell. For example, a WL driver can apply a WL pulse on a WL (or a row) to be asserted, thereby turning on the respective access transistors of memory cells arranged on (or coupled to) that row (WL). Concurrently, the bit line (BL) and the bit line bar (BLB) of a certain column may be biased with a first voltage and a second voltage corresponding to a logical “0” and a logical “1,” respectively, thereby writing a data bit to a memory cell arranged at the intersection of the asserted WL and biased BL/BLB.

Although such a writing scheme is sufficient in many contexts, in some instances, the WL pulse provided by a WL driver may take unduly long to propagate along a length of the WL, due to parasitic resistances and parasitic capacitances associated with the WL. This is particularly true in advanced complementary metal oxide semiconductor (CMOS) processes, where the WLs can have relatively narrow pitches (resulting in increased resistances relative to previous technology nodes) and where neighboring WLs can be closely spaced (resulting in increased capacitance relative to previous technology nodes). These larger RC values lead to a large RC time constant and slow slew rate for the WL when a WL pulse is first applied. Accordingly, the existing memory circuits, implementing WLs to control access, have not been entirely satisfactory in certain aspects.

The present disclosure provides various embodiments of a memory circuit (or device) that includes a WL driver and a WL booster circuit physically disposed on the opposite ends of WLs of a memory (cell) array. In some embodiments, the WL driver and the WL booster circuit can operatively perform the same function, e.g., driving the WL asserted according to a decoded address signal. Further, a total number of the WLs (N) can be divided into a plural number (N/K) of groups, with each group having one boost WL and one subgroup (K) of buffers. The boost WL can be operatively coupled between the WL driver and the booster circuit, and be configured to transmit a boost signal from the WL driver to each of the corresponding buffers. By having essentially two WL drivers disposed on the opposite ends of the WLs, memory cells disposed at the far end of the WLs can be advantageously immune from suffering the deceased WL voltage. As a result, the slew rate for the WL can be significantly improved. Further, with multiple WLs sharing one boost WL, precious real estate in one or more metallization layers can be released, which allows more area to allocate other metal tracks in the metallization layers.

In a non-limiting example where K=2, the booster circuit, physically disposed on one side of a memory array with a plural number of WLs, can include N/2 groups. Each of the booster groups can include a first buffer and a second buffer. The first buffer can correspond to (be coupled to) a first one of the WLs, and the second buffer can correspond to (be coupled to) a second one of the WLs. The WL driver, physically disposed on the other side of the memory array, can include N/2 logic gates. Each of the logic gates can receive a first input signal (e.g., a first bit of a decoded address signal) and a second input signal (e.g., a second bit of the decoded address signal), which correspond to asserting/de-asserting the first WL and second WL, respectively. The logic gates can each provide the first buffer and second buffer with a boost signal, by NOR'ing the first and second input signals. A such, the asserted WL can be applied with the first or second input signal and the boost signal from its both ends, respectively.

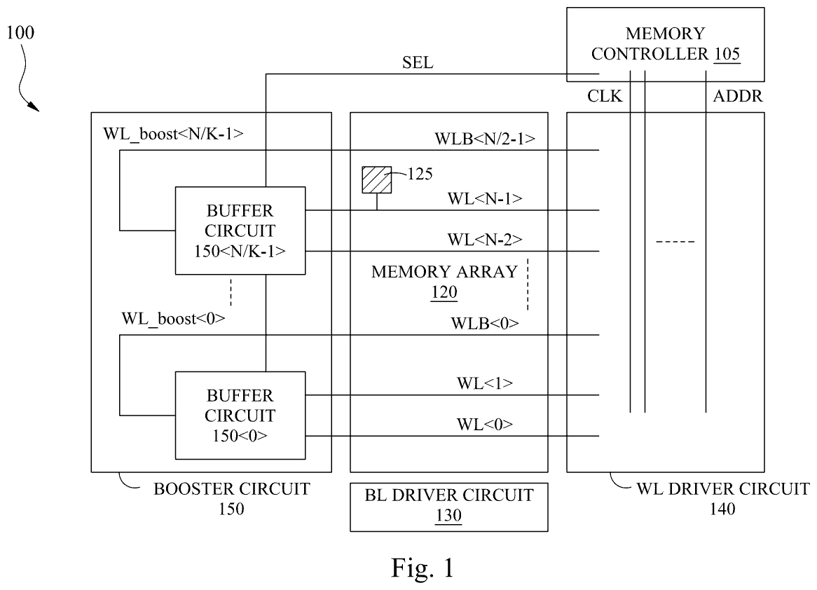

FIG. 1 illustrates a schematic diagram of a memory circuit (or device) 100, in accordance with one embodiment. In some embodiments, the memory circuit 100 includes a memory controller 105 and a memory array 120. The memory array 120 may include a plurality of storage circuits or memory cells 125 arranged in two- or three-dimensional arrays. Each memory cell 125 may be coupled to a corresponding word line WL and a corresponding pair of bit lines BLs. The memory controller 105 may write data to or read data from the memory array 120 according to electrical signals through word lines WL and bit lines BL. In other embodiments, the memory circuit 100 includes more, fewer, or different components than shown in FIG. 1.

The memory array 120 is a hardware component that stores data. In one aspect, the memory array 120 is embodied as a semiconductor memory device. The memory array 120 includes a plurality of storage circuits or memory cells 125. The memory array 120 includes a first number of nominal word lines WLs, e.g., WL<0>, WL<1> . . . WL<N−1>, and a second number of boost word lines WLBs, e.g., WLB<0>, WLB<1> . . . WLB<N/K−1>. In some embodiments, K can be any integer larger than 2 and a factor of N. As a non-limiting example which will be discussed below, K is equal to 2. Each of the nominal word lines WLs and the boost word lines WLBs can extend in a first direction. The memory array 120 includes a third number of bit lines BLs (not shown in FIG. 1). Each of the bit lines BLs can extend in a second direction. The word lines WLs, boost word lines WLBs, and the bit lines BLs may each be implemented as a conductive metal or conductive rail.

In one configuration, each memory cell 125 is coupled to a corresponding word line WL and a corresponding pair of bit lines BL and BLB, and can be operated according to voltages or currents through the corresponding word line WL and the corresponding bit lines BL/BLB. The bit lines BL, BLB may receive and/or provide differential signals. Each memory cell 125 may include a volatile memory, a non-volatile memory, or a combination of them. In some embodiments, each memory cell 125 is embodied as a static random access memory (SRAM) cell or other type of memory cell. In some embodiments, the memory array 120 includes additional lines (e.g., select lines, reference lines, reference control lines, power rails, etc.).

The memory controller 105 is a hardware component that can control operations of the memory array 120. In some embodiments, the memory circuit 100 further includes a BL controller (or driver circuit) 130, a WL controller (or driver circuit) 140, and a WL booster circuit 150. The BL driver circuit 130, the WL driver circuit 140, and the WL booster circuit 150 may each be embodied as logic circuits, analog circuits, or a combination of them. In some embodiments, the WL driver circuit 140 is a circuit that can provide a voltage or current (e.g., a WL pulse) through an asserted word line WL of the memory array 120, and the BL driver circuit 130 is a circuit that can provide or sense a voltage or current through one or more bit lines BL of the memory array 120. The WL booster circuit 150 is a circuit that includes the second number of buffer circuits, e.g., 150<0> . . . 150<N/K−1>, corresponding to the boost word lines WLBs, respectively. Each of the buffer circuits can receive a corresponding boost signal, WL_boost, from the WL driver circuit 140 and selectively invert the boost signal to the asserted word line WL. In some other embodiments, the memory circuit 100 can include more, fewer, or different components than shown in FIG. 1. For example, the memory circuit 100 can further include a timing controller that can provide control signals or clock signals to synchronize operations of the BL driver circuit 130 and the WL driver circuit 140.

As a brief overview, the memory controller 105 can provide a clock (CLK) signal and an (encoded) address (ADDR) signal to the WL driver circuit 140. Upon receiving the ADDR signal, the WL driver circuit 140 can decode the ADDR signal. The decoded ADDR signal can include a plural number of bits (e.g., N bits), one of which has a first logic state (e.g., a logical 1) corresponding to one of the nominal word lines WLs to be asserted (or selected), with the rest of which have a second logic state (e.g., a logical 0) corresponding to other nominal word lines WLs to be de-asserted (or deselected). The WL driver circuit 140 can apply those decoded bits to the word lines WL<0>, WL<1> . . . WL<N−1>, respectively. Concurrently, the WL driver circuit 140 can include a plural number of logic gates (e.g., N/K−1 NOR gates), each of which can provide a boost signal, e.g., WL_boost<0>, to a corresponding one of the buffer circuits, e.g., 150<0>. The buffer circuits each have K buffers coupled to K of the word lines WLs, respectively. The NOR gate of the WL driver circuit 140 can generate the boost signal based on the bits of the decoded ADDR signal applied to the corresponding K word lines WLs, respectively. Based on an enablement (SEL) signal received from the memory controller 105, one of the K buffers can logically invert the boost signal to the asserted word line WL, with the rest of the buffers forwarding the boost signal to the de-asserted word line(s) WL(s).

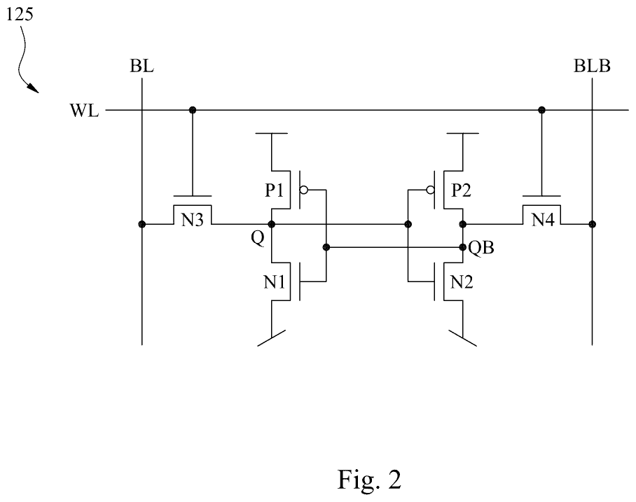

FIG. 2 illustrates an example circuit diagram of the memory cell 125, which is implemented as an SRAM cell (hereinafter “SRAM cell 125”), in accordance with one embodiment. In the illustrative example of FIG. 2, the SRAM cell 125 includes six transistors (sometimes referred to as 6T SRAM cell): four n-type transistors N1, N2, N3, N4 and two p-type transistors P1, P2. However, it should be understood that the SRAM memory cell 125 can include any suitable number of transistors (e.g., 7, 8, 10) while remaining within the scope of the present disclosure. The n-type transistors N1, N2, N3, N4 may be n-type metal-oxide-semiconductor field-effect transistors (MOSFET). The p-type transistors P1, P2 may be p-type MOSFET. These components may operate together to store a bit. In other embodiments, the SRAM cell 125 includes more, fewer, or different components than shown in FIG. 2.

The n-type transistors N3, N4 include gate electrodes coupled to a word line WL. In one configuration, a drain electrode of the n-type transistor N3 is coupled to a bit line BL, and a source electrode of the n-type transistor N3 is coupled to a port Q. In one configuration, a drain electrode of the n-type transistor N4 is coupled to a bit line BLB, and a source electrode of the n-type transistor N4 is coupled to a port QB. In one aspect, the n-type transistors N3, N4 operate as electrical switches. The n-type transistors N3, N4 may allow the bit line BL to electrically couple to or decouple from the port Q and allow the bit line BLB to electrically couple to or decouple from the port QB, according to a voltage applied to the word line WL. For example, according to a supply voltage VDD (or 1V) corresponding to a high state (or logical 1) applied to the word line WL, the n-type transistor N3 is enabled to electrically couple the bit line BL to the port Q and the n-type transistor N4 is enabled to electrically couple the bit line BLB to the port QB. For another example, according to a ground voltage VSS (or 0V) corresponding to a low state (or logical 0) applied to the word line WL, the n-type transistor N3 is disabled to electrically decouple the bit line BL from the port Q and the n-type transistor N4 is disabled to electrically decouple the bit line BLB from the port QB.

The n-type transistor N1 includes a source electrode coupled to a first supply voltage rail supplying the ground voltage VSS or 0V, a gate electrode coupled to the port QB, and a drain electrode coupled to the port Q. In one configuration, the p-type transistor P1 includes a source electrode coupled to a second supply voltage rail supplying the supply voltage VDD, a gate electrode coupled to the port QB, and a drain electrode coupled to the port Q. In one configuration, the n-type transistor N2 includes a source electrode coupled to the first supply voltage rail supplying the ground voltage VSS or 0V, a gate electrode coupled to the port Q, and a drain electrode coupled to the port QB. In one configuration, the p-type transistor P2 includes a source electrode coupled to the second supply voltage rail supplying the supply voltage VDD, a gate electrode coupled to the port Q, and a drain electrode coupled to the port QB. In this configuration, the n-type transistor N1 and the p-type transistor P1 operate as an inverter, and the n-type transistor N2 and the p-type transistor P2 operate as an inverter, such that two inverters form cross-coupled inverters. In one aspect, the cross-coupled inverters may sense and amplify a difference in voltages at the ports Q, QB. When writing data, the cross-coupled inverters may sense voltages at the ports Q, QB provided through the n-type transistors N3, N4 and amplify a difference in voltages at the bit lines BL, BLB. For example, the cross-coupled inverters sense a voltage 0.5 V at the port Q and a voltage 0.4V at the port QB, and amplify a difference in the voltages at the ports Q, QB through a positive feedback (or a regenerative feedback) such that the voltage at the port Q becomes the supply voltage VDD (e.g., 1V) and the voltage at the port QB becomes the ground voltage VSS (e.g. 0V). The amplified voltages at the ports Q, QB may be provided to the bit lines BL, BLB through the n-type transistors N3, N4, respectively for reading.

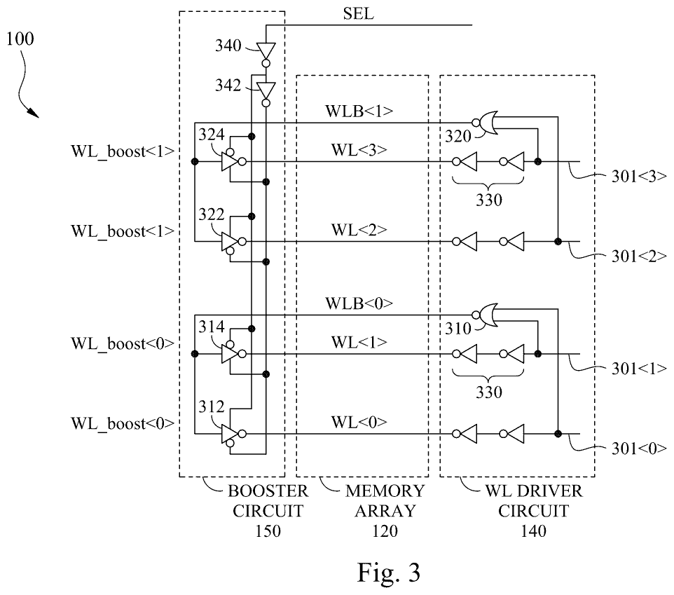

FIG. 3 illustrates an example circuit diagram of a portion of the memory circuit 100 of FIG. 1, in accordance with some embodiments. For example, the memory array 120, the WL driver circuit 140, and the WL booster circuit 150 are each partially shown. Further, in FIG. 3, an implementation of the memory circuit 100 where K=2 is shown. As such, the WL driver circuit 140 can include N/2 logic gates, each of which is configured to generate a respective boost signal. Further, each of the boost signals can be received by a respective buffer circuit that includes 2 (or a pair of) buffers. It should be understood that the circuit diagram of FIG. 3 is provided merely for illustrative purposes, and not intended to limit the scope of the present disclosure.

In FIG. 3, four nominal word lines WLs of the memory array 120, e.g., WL<0>, WL<1>, WL<2>, and WL<3>, are shown. Each of the nominal word lines WLs is coupled to a certain number of the memory cells 125. Each of the nominal word lines WLs extends along a lateral direction, with the WL driver circuit 140 and the WL booster circuit 150 physically disposed on opposite ends of the word line WLs, respectively. The WL driver circuit 140 includes logic gates, 310 and 320, and the WL booster circuit 150 includes buffers, 312, 314, 322, and 324.

In some embodiments, the logic gates 310 and 320 can each be implemented as a NOR gate that has first and second inputs and one output. The first input and the second input are coupled to a corresponding first word line WL1 and a corresponding second word line WL2, respectively, and the output is coupled to a corresponding pair of the buffers through a common boost word line WLB. The first word line WL1 (or the first input of the NOR gate) and the second word line WL2 (or the second input of the NOR gate) are applied with a first bit and a second bit of a decoded ADDR signal, respectively, and the common boost word line WLB (or the output of the NOR gate) is applied with a boost signal (WL_boost) which is a NOR'ed combination of the first and second decoded bits. Such a pair of buffers, corresponding to the common boost word line WLB, can be alternately activated based on an enablement (SEL) signal, e.g., provided by the memory controller 105. When the SEL signal is provided at a first logic state, one of the buffers can be activated to logically invert the received WL_boost signal; and when the SEL signal is provided at a second logic state, the other one of the buffers can be deactivated to forward the received WL_boost signal (i.e., without logically inverting it). As such, one of the nominal word lines WLs can be asserted at a time (e.g., during one clock cycle), and the asserted word line WL can be applied with signals through both of its ends from the WL driver 140 and the WL booster circuit 150, respectively.

For example, the NOR gate 310 has first and second inputs coupled to the word lines, WL<0> and WL<1>, respectively. The word line WL<0> can be applied with, or correspond to, a first bit of a decoded ADDR signal, 301<0>; and the word line WL<1> can be applied with, or correspond to, a second bit of the decoded ADDR signal, 301<1>. Each of these decoded address bits (sometimes referred to as WL assertion signals), 301<0> and 301<1>, can be applied to the corresponding one of word lines WL<0> and WL<1> through an even number of buffers, e.g., 330. Upon receiving the decoded address bits, the NOR gate 310 can perform a NOR operation on those bits to provide a boost signal, e.g., WL_boost<0>, on its output. Accordingly, a logic state of the boost signal, WL_boost<0>, can be determined according to respective logic states of the decoded address bits, 301<0> and 301<1>, which follows the Table listed below. The boost signal, WL_boost<0>, can be provided to the buffers 312 and 314 of the WL booster circuit 150 through a common boost word line, e.g., WLB<0>. Concurrently or subsequently, the SEL signal is provided to a first enablement input of the buffer 312 through inverter 340 and to a second enablement input of the buffer 312 through inverters 340 and 342; and the SEL signal is provided to a first enablement input of the buffer 314 through inverter 340 and to a second enablement input of the buffer 314 through inverters 340 and 342, allowing the buffers 312 and 314 to be alternately activated.

TABLE

| 301<0> | 301<1> | WL_boost<0> |
|---|---|---|
| 0 | 0 | 1 |
| 0 | 1 | 0 |
| 1 | 0 | 0 |
| 1 | 1 | 0 |

In a non-limiting example where the word line WL<0> is selected or asserted, the decoded address bits, 301<0> and 301<1>, are provided with logical 1 and logical 0, respectively. As such, the word line WL<0> is applied with logical 1, and the word line WL<1> is applied with logical 0, and the NOR gate 310 outputs the boost signal WL_boost<0> with logical 0. Based on the implementation, the SEL signal can be provided with logical 1 or 0, but in some embodiments of the present disclosure, the SEL signal may remain at that logical state prior to the logical 1 being applied to the word line WL<0>. In the current example, the buffer 312 can be activated by the SEL signal to invert the boost signal WL_boost<0>, while the buffer 314 can be deactivated by the SEL signal to forward the boost signal WL_boost<0>. Accordingly, the buffer 312 (of the WL booster circuit 150) provides logical 1 to the word line WL<0> through one of its ends, while simultaneously the WL driver circuit 140 provides logical 1 to the word line WL<0> through the other end.

Configurations of the NOR gate 320, word lines WL<2> and WL<3>, boost word line WL<1>, buffers 322 and 324, and associated signals, 301<2>, 302<3>, and WL_boost<1> are substantially similar to the NOR gate 310 and its corresponding components (e.g., word lines WL<0> and WL<1>, boost word line WL<0>, buffers 312 and 314, etc.), and thus, the description is not repeated.

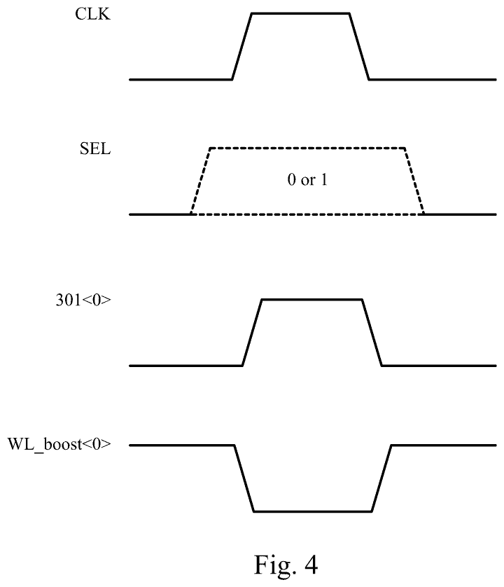

FIG. 4 illustrates respective waveforms of various above-described signals, in accordance with some embodiments. For example, the clock (CLK) signal, the enablement (SEL) signal, the WL assertion signal (e.g., decoded address bit 301<0>), and the boost signal (e.g., WL_boost<0>), are shown. Following the above example where the word line WL<0> is asserted/selected, in FIG. 4, the SEL signal remains at logical 1 or 0, prior to the decoded address bit 301<0> being pulled up and subsequently to the decoded address bit 301<0> being pulled down. As one of the decoded address bits, 301<0> and 301<1>, is at logical 1, the boost signal WL_boost<0> is pulled down. Stated another way, as one of the decoded address bits, 301<0> and 301<1>, is pulled up, the boost signal WL_boost<0> is pulled down.

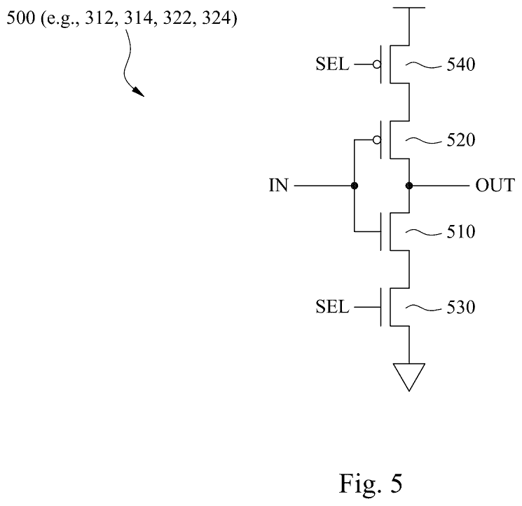

FIG. 5 illustrates an example circuit diagram of the buffer (e.g., 312, 314, 322, 324) of the WL booster circuit 150 (hereinafter “buffer 500”), in accordance with some embodiments. Although the circuit diagram of FIG. 3 implements the buffer 500 as a transmission gate, it should be appreciated that the buffer 500 can be implemented as any of various other suitable circuits while remaining within the scope of the present disclosure.

As shown, in FIG. 5, the buffer 500 can include transistors 510, 520, 530, and 540 coupled in series and between a supply voltage (e.g., VDD) and a reference voltage (e.g., VSS). The transistors 510 and 530 are each implemented as an n-type field-effect-transistor, and the transistors 520 and 540 are each implemented as a p-type field-effect-transistor. The transistors 510 and 520 can have their gate terminals connected to each other as an input of the buffer 500, and their drain terminals connected to each other as an output of the buffer 500. The transistor 510 can have its source terminal connected to a drain terminal of the transistor 530, with a source terminal of the transistor 530 connected to VSS; and the transistor 520 can have its source terminal connected to a drain terminal of the transistor 540, with a source terminal of the transistor 540 connected to VDD. Further, the transistor 530 can have its gate terminal configured as a first enablement input to receive the SEL signal; and the transistor 540 can have its gate terminal configured as a second enablement input to receive the SEL signal.

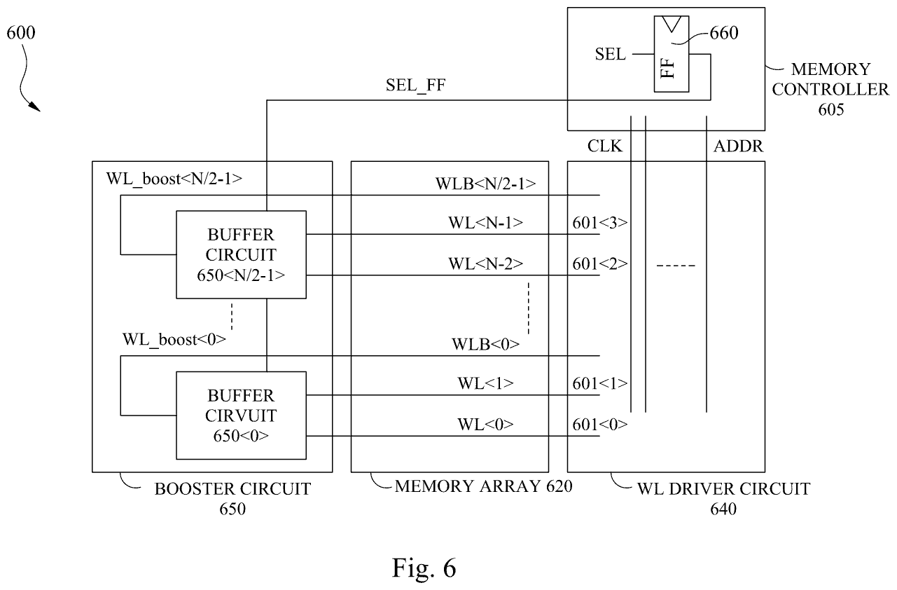

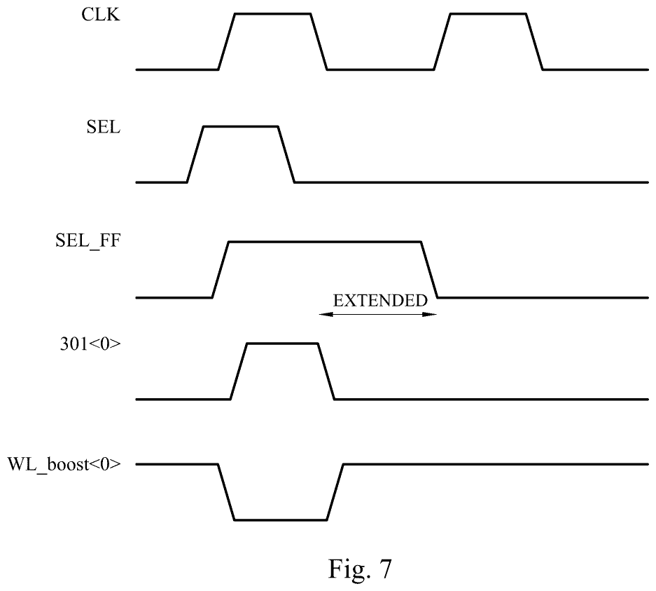

FIG. 6 illustrates a schematic diagram of a memory circuit (or device) 600, in accordance with one embodiment. The memory circuit 600 is substantially similar to the memory circuit 100, except that the memory circuit 600 further includes a flip-flop circuit embedded in its memory controller. For example, the memory circuit 600 also includes a memory controller 605 (which further includes a flip-flop circuit 660), a memory array 620, a WL driver circuit 640, and a WL booster circuit 650. Accordingly, the following discussion of the memory circuit 600 will be focused on the difference. In some embodiments, the flip-flop circuit 660 may be embedded in the memory controller 605 that is configured to provide the CLK signal and the ADDR signal. With the flip-flop circuit 660, the memory controller 605 can provide an extended version of the SEL signal. For example, the flip-flop circuit 660 can extend a falling edge of the SEL signal and output an SEL__FF signal to control the buffer circuits of the WL booster circuit 650, as shown in the waveforms of FIG. 7. The SEL_FF signal can extend a hold time of the SEL_FF signal, which advantageously ensures a logic state of the SEL_FF signal to remain the same for an extended period of time even after the WL assertion signal (e.g., 601<0>) is pulled down.

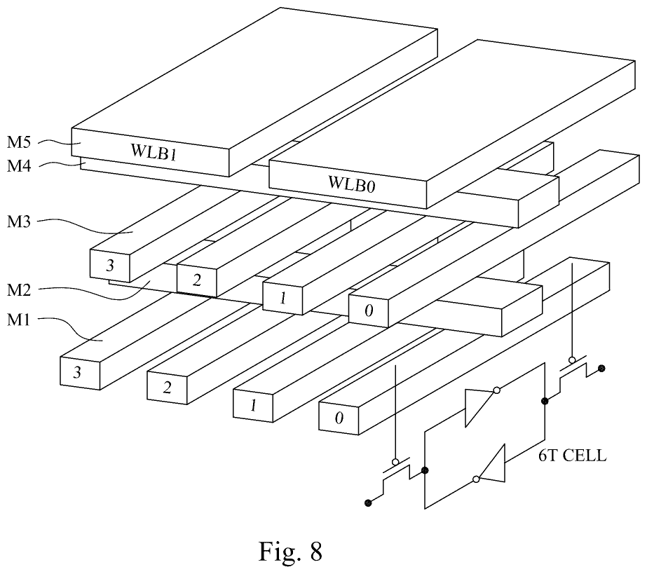

FIG. 8 illustrates a schematic view of a portion of the above-described memory circuit (e.g., the memory circuit 100, 600), in accordance with some embodiments. As shown, one of the memory cells 125, which is implemented as a 6T SRAM cell, can be formed along the major surface of a substrate, sometimes referred to as part of front-end-of-line (FEOL) processing. Over the FEOL processing, a plural number of metallization layers, sometimes referred to as back-end-of-line (BEOL) processing, can be formed. Each of the metallization layers can include a number of metal tracks embedded in a dielectric material. Those metallization layers are typically referred to as an optional M0 layer, M1 layer, M2 layer, M3 layer, M4 layer, M5 layer, and so on (from the bottommost to the topmost), and the metal track embedded therein are typically referred to as M0 tracks, M1 tracks, M2 tracks, M3 tracks, M4 tracks, M5 tracks, and so on, respectively. In some embodiments, the nominal word lines WLs (e.g., WL<0>, WL<1>, WL<2>, WL<3> of FIG. 3) may be formed in the M1 layer and/or the M3 layer, and the boost word lines WLBs (e.g., WL<0>, WL<1> of FIG. 3) may be formed in a different metallization layer (e.g., the M5 layer). These word lines, WLs and WLBs, can extend along the same lateral direction, and the boost word lines WLBs have a wider width (extending in a direction perpendicular to the lengthwise direction of the word lines WLs and WLBs) than the nominal word lines WLs do.

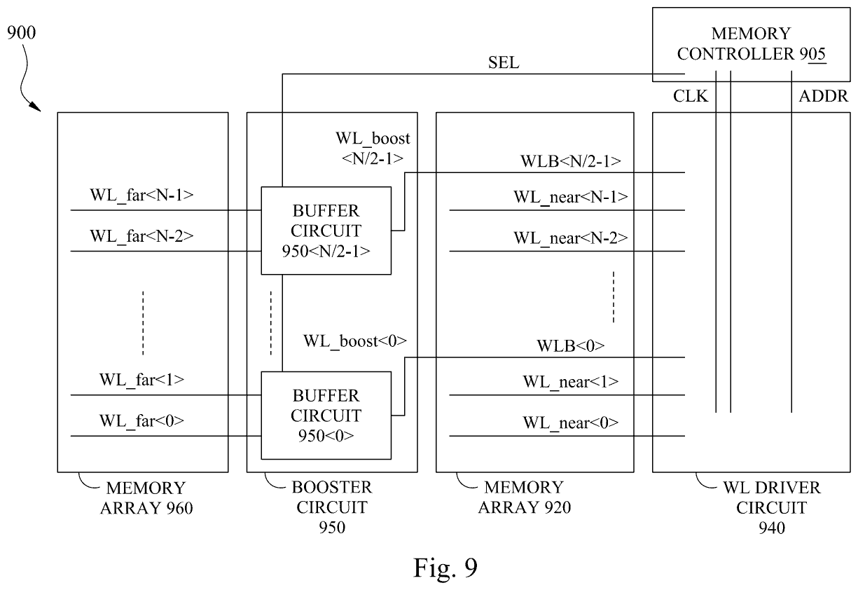

FIG. 9 illustrates a schematic diagram of a memory circuit (or device) 900, in accordance with one embodiment. The memory circuit 900 is substantially similar to the memory circuit 100, except that the memory circuit 900 includes an additional memory array 960. For example, the memory circuit 900 also includes a memory controller 905, a memory array 920, a WL driver circuit 940, and a WL booster circuit 950. Accordingly, the following discussion of the memory circuit 900 will be focused on the difference.

In some embodiments, the WL booster circuit 950 is physically interposed between the memory array 920 and the memory array 960, with the WL driver circuit 940 disposed on one end of the memory array 920 opposite to the other end that is closer to the WL booster circuit 950. Accordingly, the memory array 920 is sometimes referred to as a near array, and the memory array 960 is sometimes referred to as a far array. The WL driver circuit 940 can apply first WL assertion signals on corresponding nominal word lines of the memory array 920, e.g., WL_near<0>, WL_near<1> . . . WL_near<N−2>, and WL_near<N−1>; and the WL booster circuit 950 can apply second WL assertion signals on corresponding nominal word lines of the memory array 960, e.g., WL_far<0>, WL_far<1> . . . WL_far<N−2>, and WL_far<N−1>.

Further, in the example of K=2 (e.g., where two nominal word lines WLs correspond to one boost word line WLB), N/2 boost word lines WLBs (e.g., WLB<0> . . . WLB<N/2-1>) can be operatively coupled between the WL driver circuit 940 and the WL booster circuit 950, just like the example of FIG. 1 of FIG. 6. Differently, upon receiving the boost signals (e.g., WL_boost<0> . . . WL_boost<N/2−1>) through the boost word lines WLBs, the WL booster circuit 950 can assert one of the nominal word lines at a time based on the boost signals. For example, the WL booster circuit 950 can include N/2 buffer circuits, e.g., 950<0> . . . 950<N/2−1>. Each of the buffer circuits can assert one of a corresponding pair of nominal word lines, e.g., the pair of WL_far<0> and WL_far<1> . . . the pair of WL_far<N−2> and WL_far<N−1>, at a time using the corresponding boost signal.

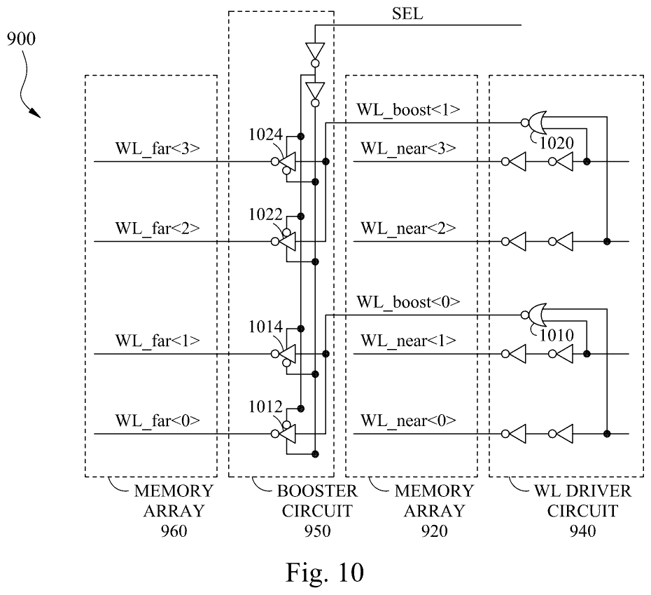

FIG. 10 illustrates an example circuit diagram of a portion of the memory circuit 900 of FIG. 9, in accordance with some embodiments. For example, the memory arrays 920 and 960, the WL driver circuit 940, and the WL booster circuit 950 are each partially shown. It should be understood that the circuit diagram of FIG. 10 is provided merely for illustrative purposes, and not intended to limit the scope of the present disclosure.

In FIG. 10, four nominal word lines WLs of the memory array 920, e.g., WL_near<0>, WL_near<1>, WL_near<2>, and WL_near<3>, and four nominal word lines of the memory array 960, e.g., WL_far<0>, WL_far<1>, WL_far<2>, and WL_far<3>, are shown. Each of the nominal word lines WLs of the memory arrays 920 and 960 extends along a lateral direction. The WL booster circuit 950 is physically interposed between the memory array 920 and the memory array 960 along the lateral direction, and the WL driver circuit 940 is disposed on one end of the nominal word lines, WL_near<0> to WL_near<3>, that is opposite to the other end closer to the WL booster circuit 950. The WL driver circuit 940 includes logic gates (e.g., NOR gates), 1010 and 1020, and the WL booster circuit 950 includes buffers, 1012, 1014, 1022, and 1024. Each of the buffers 1012 to 1024 may be implemented as a transmission gate.

The buffers 1012-1014 may operatively form one of the buffer circuits (e.g., 950<0> . . . 950<N/2−1>), and the buffers 1022-1024 may operatively form another one of the buffer circuits (e.g., 950<0> . . . 950<N/2−1>). The buffers 1012 and 1014 can receive boost signal WL_boost<0> from the NOR gate 1010 that receives decoded address bits applied on the nominal word lines WLs WL_near<0> and WL_near<1>, respectively; and the buffers 1022 and 1024 can receive boost signal WL_boost<1> from the NOR gate 1020 that receives decoded address bits applied on the nominal word lines WLs WL_near<2> and WL_near<3>, respectively. The buffers 1012 and 1014 can receive the SEL signal using different enablement inputs (so as to alternately activate the buffers 1012-1014), and the buffers 1022 and 1024 can receive the SEL signal using different enablement inputs (so as to alternately activate the buffers 1022-1024). The buffer 1012 can receive the boost signal WL_boost<0>, logically invert or forward the boost signal WL_boost<0> based on a logic state of the SEL signal, and provide the inverted/forwarded boost signal WL_boost<0> to the nominal word line WL_far<0>; and the buffer 1014 can receive the boost signal WL_boost<0>, logically invert or forward the boost signal WL_boost<0> based on a logic state of the SEL signal, and provide the inverted/forwarded boost signal WL_boost<0> to the nominal word line WL_far<1>. Similarly, the buffer 1022 can receive the boost signal WL_boost<1>, logically invert or forward the boost signal WL_boost<1> based on a logic state of the SEL signal, and provide the inverted/forwarded boost signal WL_boost<1> to the nominal word line WL_far<2>; and the buffer 1024 can receive the boost signal WL_boost<1>, logically invert or forward the boost signal WL_boost<1> based on a logic state of the SEL signal, and provide the inverted/forwarded boost signal WL_boost<1> to the nominal word line WL_far<3>.

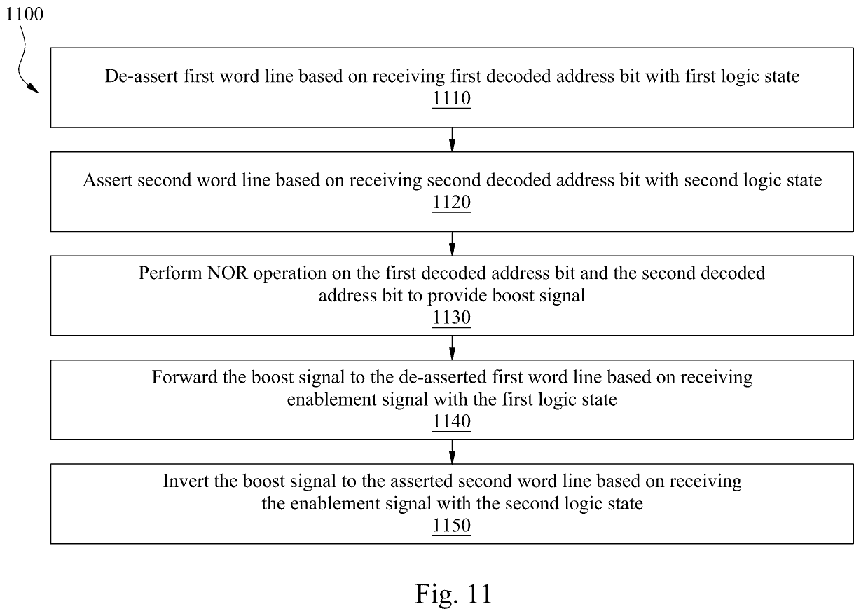

FIG. 11 illustrates a flow chart of a method 1100 for operating memory circuits, in accordance with some embodiments. The example method 1100 can be performed by any of the above-discussed memory circuit 100 (FIG. 1), 600 (FIG. 6), or 900 (FIG. 9). As such, the following embodiment of the method 1100 can be described in conjunction with but not limited to at least one of FIG. 1, 6, or 9. The illustrated embodiment of the method 1100 is provided as an example and does not intent to limit the scope of the present disclosure. Therefore, it shall be understood that any of a variety of the operations of the method 1100 may be omitted, re-sequenced, and/or added while remaining within the scope of the present disclosure.

The method 1100 starts with operation 1110 of de-asserting a first nominal word line based on receiving a first decoded address bit with a first logic state, and continues to operation 1120 of asserting a second nominal word line based on receiving a second decoded address bit with a second logic state. Using the memory circuit 100 as a representative example, when the nominal word line WL<1> is de-asserted and the nominal word line WL<0> is asserted, the WL driver circuit 140 can apply a first bit of the decoded ADDR signal (e.g., 301<0>) and a second bit of the decoded ADDR signal (e.g., 301<1>) on the nominal word lines WL<0> and WL<1>, respectively. In one non-limiting aspect, the first bit (301<0>) and the second bit (301<1>) can be equal to logical 1 and logical 0, respectively.

The method 1100 continues to operation 1130 of performing a NOR operation on the first decoded address bit and the second decoded address bit to provide a boost signal. Continuing with the above example, the WL driver circuit 140, or a corresponding one of its NOR gates configured to receive the first bit (301<0>) and the second bit (301<1>), can NOR the first bit (301<0>) and the second bit (301<1>) to provide the boost signal WL_boost<0>. The WL driver circuit 140 can apply the boost signal WL_boost<0> to a corresponding buffer circuit (e.g., 150<0>) of the WL booster circuit 150 through a boost word line WLB (e.g., WLB<0>). In some embodiments, each of the buffer circuits can include plural buffers with a number corresponding to the number (e.g., 2) of nominal word lines coupled to a boost word line. Each of the buffers can correspond to (or be coupled to) a corresponding one of the nominal word lines WLs.

The method 1100 continues to operation 1140 of forwarding the boost signal to the de-asserted first word line based on receiving an enablement signal with the first logic state, and operation 1150 of inverting the boost signal to the asserted second word line based on receiving the enablement signal with the second logic state. Still with the above example where each buffer circuit includes a first buffer (e.g., 312) and a second buffer (e.g., 314), the first buffer 312, coupled to the nominal word line WL<0>, can logically invert the boost signal WL_boost<0> and provided the inverted version to the nominal word line WL<0> based on receiving a first logic state of the SEL signal at its first enablement input, while the second buffer 314, coupled to the nominal word line WL<1>, can forward the boost signal WL_boost<0> to the nominal word line WL<1> based on receiving a second logic state of the SEL signal at its first enablement input.

In one aspect of the present disclosure, a memory circuit is disclosed. The memory circuit includes a memory array comprising a plurality of memory cells arranged across a first number (N) of word lines; a word line driver comprising a second number (N/2) of logic gates, wherein each of the logic gates is configured to receive a first input signal corresponding to a first one of the word lines and a second input signal corresponding to a second one of the word lines, and configured to provide a boost signal based on respective logic states of the first and second input signals; and a booster circuit comprising N/2 pairs of first and second buffers, wherein each of the first buffers is configured to receive the corresponding boost signal and de-assert the corresponding first word line, and each of the second buffers is configured to receive the corresponding boost signal and assert the corresponding second word line.

In another aspect of the present disclosure, a memory circuit is disclosed. The memory circuit includes a plurality of first memory cells arranged along a first word line extending along a lateral direction; a plurality of second memory cells arranged along a second word line extending along the lateral direction; a logic gate disposed on a first end of the first and second word lines in the lateral direction, wherein the logic gate is configured to receive a first input signal corresponding to the first word line and a second input signal corresponding to the second the word line, and configured to provide a boost signal through a boost word line based on respective logic states of the first and second input signals; a first buffer disposed on a second end of the first and second word lines in the lateral direction, wherein the first buffer is configured to receive the boost signal and de-assert the first word line based on receiving a first logic state of an enablement signal; and a second buffer disposed on the second end of the first and second word lines in the lateral direction, wherein the second buffer is configured to receive the boost signal and assert the second word line based on receiving a second logic state of the enablement signal.

In yet another aspect of the present disclosure, a method for operating memory circuits is disclosed. The method includes de-asserting a first word line based on receiving a first decoded address bit with a first logic state; asserting a second word line based on receiving a second decoded address bit with a second logic state; performing a NOR operation on the first decoded address bit and the second decoded address bit to provide a boost signal; forwarding the boost signal to the de-asserted first word line based on receiving an enablement signal with the first logic state; and inverting the boost signal to the asserted second word line based on receiving the enablement signal with the second logic state.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array comprising a plurality of memory cells arranged across a first number (N) of word lines;
a word line driver comprising a second number (N/2) of logic gates, wherein each of the logic gates is configured to receive a first input signal corresponding to a first one of the word lines and a second input signal corresponding to a second one of the word lines, and configured to provide a boost signal based on respective logic states of the first and second input signals; and
a booster circuit comprising N/2 pairs of first and second buffers, wherein each of the first buffers is configured to receive the corresponding boost signal and de-assert the corresponding first word line, and each of the second buffers is configured to receive the corresponding boost signal and assert the corresponding second word line.

2. The memory circuit of claim 1, wherein the logic gates each include a NOR gate.

3. The memory circuit of claim 1, wherein the buffers each include a transmission gate.

4. The memory circuit of claim 1, wherein the first buffer and the second buffer of each pair are configured to receive a first logic state and a second logic state of an enablement signal, respectively.

5. The memory circuit of claim 1, wherein each of the word lines physically extends along a lateral direction.

6. The memory circuit of claim 5, wherein the word line driver is physically disposed on a first end of the word lines along the lateral direction, and the booster circuit is physically disposed on a second end of the word lines opposite to the first end along the lateral direction.

7. The memory circuit of claim 4, further comprising a flip-flop circuit.

8. The memory circuit of claim 7, wherein the flip-flop circuit is configured to extend a pulse window of the enablement signal.

9. The memory circuit of claim 1, wherein the memory cells of the memory array are arranged across N/2 boost word lines.

10. The memory circuit of claim 9, wherein the word lines and the boost word lines are disposed in respectively different metallization layers.

11. The memory circuit of claim 9, wherein the word lines are formed as first metal tracks with a first width, respectively, and the boost word lines are formed as second metal tracks with a second width, respectively, and wherein the first width is less than the second width.

12. A memory circuit, comprising:
a plurality of first memory cells arranged along a first word line extending along a lateral direction;
a plurality of second memory cells arranged along a second word line extending along the lateral direction;
a logic gate disposed on a first end of the first and second word lines in the lateral direction, wherein the logic gate is configured to receive a first input signal corresponding to the first word line and a second input signal corresponding to the second the word line, and configured to provide a boost signal through a boost word line based on respective logic states of the first and second input signals;
a first buffer disposed on a second end of the first and second word lines in the lateral direction, wherein the first buffer is configured to receive the boost signal and de-assert the first word line based on receiving a first logic state of an enablement signal; and
a second buffer disposed on the second end of the first and second word lines in the lateral direction, wherein the second buffer is configured to receive the boost signal and assert the second word line based on receiving a second logic state of the enablement signal.

13. The memory circuit of claim 12, wherein the logic gate includes a NOR gate.

14. The memory circuit of claim 12, wherein the first and second buffers each includes a transmission gate.

15. The memory circuit of claim 12, wherein the boost word line also extends along the lateral direction.

16. The memory circuit of claim 12, wherein the first and second word lines are disposed in a first metallization layer, and the boost word line is disposed in a second, different metallization layer.

17. The memory circuit of claim 12, wherein the first and second word lines are each formed as a first metal track with a first width, and the boost word line is formed as a second metal track with a second width, and wherein the first width is less than the second width.

18. The memory circuit of claim 12, wherein the enablement signal remains at the first or second logic state, prior to asserting the second word line.

19. A method for operating memory circuits, comprising:
de-asserting a first word line based on receiving a first decoded address bit with a first logic state;
asserting a second word line based on receiving a second decoded address bit with a second logic state;
performing a NOR operation on the first decoded address bit and the second decoded bit signal to provide a boost signal;
forwarding the boost signal to the de-asserted first word line based on receiving an enablement signal with the first logic state; and
inverting the boost signal to the asserted second word line based on receiving the enablement signal with the second logic state.

20. The method of claim 19, wherein the enablement signal remains at the first or second logic state, prior to asserting the second word line.
